(19) United States
(12) Patent Application Publication
(10) Pub. No.: US 2004/0187767 A1
(43) Pub. Date: Sep. 30, 2004

(54) Device and method for multicrystalline silicon wafers

(75) Inventors: Mohan Chandra, Merrimack, NH (US); Bernard D. Jones, Amherst, NH (US); P. Santhana Raghavan, Nashua, NH (US); Carl Chartier, Manchester, NH (US); Alleppey V. Hariharan, Nashua, NH (US); Tom McGee, Concord, NH (US); Dean C. Skelton, Fitzwilliam, NH (US)

Correspondence Address: Schwegman, Lundberg, Woessner & Kluth, P.A., P.O. Box 2938, Minneapolis, MN, 55402, US

(73) Assignee: Intel Corporation

(21) Appl. No.: 10/692,611

(22) Filed: Oct. 24, 2003

Related U.S. Application Data
(60) Provisional application No. 60/421,406, filed on Oct. 24, 2002.

(51) Int. Cl. C30B 15/00; C30B 21/06; C30B 27/02; C30B 28/10; C30B 30/04

(52) U.S. Cl. 117/13

(57) ABSTRACT

A method for making ingots, and devices for making ingots are provided. Crucibles are provided that are reusable for forming multicrystalline silicon ingots. Crucibles are provided with features such as multiple components, coefficients of thermal expansion, and coatings that enhance a release of the ingots from the crucibles after cooling. Coatings on crucibles are provided that reduce or eliminate contamination of silicon ingots during formation. Methods of forming composite wafers are provided that produce a low cost wafer without sacrificing performance.

This application claims the benefit of priority under 35 U.S.C. 119(e) to U.S. Provisional Patent Application Serial No. 60/421,406, filed Oct. 24, 2002, which is incorporated herein by reference.

### TECHNICAL FIELD

The present invention relates generally to semiconductor manufacturing. Specifically the present invention relates to processing of multicrystalline silicon wafers for use in integrated circuit chip manufacture.

### BACKGROUND

In the production of integrated circuits (IC), a number of chips are typically formed on the surface of a single semiconductor wafer. After the chips are formed, the wafer is cut (diced) into a number of individual chips. Wafer material suitable for semiconductor devices such as transistors is typically a single crystal material. The most common single crystal material is currently silicon. In order to form suitable single crystal wafers, an ingot of single crystal material is typically fabricated, then sliced into a number of individual wafers. Although the semiconductor devices, such as transistors, typically only occupy a very thin portion of the surface of an individual wafer, the wafers are sliced to a larger thickness for reasons such as mechanical integrity. For example, in manufacturing, the wafer must undergo some degree of handling. Wafers need to be thick enough to withstand the handling without a mechanical failure such as cracking or breaking.

Fabrication of single crystal semiconductor material is an expensive and time consuming process. Because the actual semiconductor devices only occupy a small fraction of the total volume of the wafer, the remaining fraction of the wafer that serves primarily as a carrier is an inefficient use of the expensive single crystal semiconductor material.

What is needed is a device and method that reduces the inefficient use of single crystal material in semiconductor device fabrication.

### BRIEF DESCRIPTION OF THE DRAWINGS

FIG. 1A illustrates a side view of a crucible according to an embodiment of the invention.

FIG. 1B illustrates a top view of the crucible in FIG. 1A.

FIG. 2 illustrates a side view of a crucible according to an embodiment of the invention.

FIG. 3 illustrates a side view of another crucible according to an embodiment of the invention.

FIG. 4 illustrates a side view of a crucible and workpiece material according to an embodiment of the invention.

FIG. 5 illustrates an isometric view of another crucible according to an embodiment of the invention.

FIG. 6 illustrates a block diagram of an ingot forming system according to an embodiment of the invention.

FIG. 7 illustrates an ingot according to an embodiment of the invention.

FIG. 8 illustrates a wafer according to an embodiment of the invention.

FIG. 9 illustrates another wafer according to an embodiment of the invention.

### DETAILED DESCRIPTION

In the following detailed description of the invention reference is made to the accompanying drawings which form a part hereof, and in which are shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized, and structural, logical, and electrical changes may be made, without departing from the scope of the present invention. The following detailed description is, therefore, not to be taken in a limiting sense, and the scope of the invention should be determined with reference to the appended claims, along with the full scope of equivalents to which such claims are entitled.

In one embodiment, ingots produced using crucibles and methods described in the present disclosure are used to produce inexpensive wafers for chip manufacture that possess the necessary purity for integrated circuit chip manufacture. In one embodiment, ingots produced using crucibles and methods described in the present disclosure further provide the necessary properties such as mechanical strength to maintain a robust wafer that withstands integrated circuit processing conditions.

The process of forming silicon ingots presents a number of technical hurdles to overcome. Pure, or substantially pure silicon is very reactive with numerous other element impurities. Selected applications, such as integrated circuit chip applications require a high level of purity in a semiconductor material. The presence or absence of impurities, and the type of impurities in integrated circuit chip wafers can substantially alter electrical properties of the wafers. One desire in equipment such as crucibles used to form ingots for integrated circuit chip wafer is therefore to minimize impurity contamination from the equipment such as crucibles.

Another hurdle in the process of forming silicon ingots includes the high cost of current crucibles due to expensive crucible materials, and the difficulty in re-using crucibles to form multiple ingots from a single crucible. Most crucible materials are brittle and tend to fracture easily. Further, due to coefficient of thermal expansion mismatches, during cooling, a silicon ingot can produce pressure radially outward on crucible walls, which leads to fracture of the crucible. Additionally, silicon frequently interacts with the walls and bottom of the crucible, causing the cooled ingot to bond to the walls of the crucible. If an ingot is bonded to the walls of the crucible, either chemically, or mechanically, etc. then the ingot cannot be removed from the crucible without breaking either the crucible or the ingot.

Embodiments of crucibles described in the following descriptions address these technical hurdles and produce ingots with the necessary purity for integrated circuit wafer use, in a process that allows re-use of crucibles. Re-using crucibles substantially reduces the manufacturing cost of ingots.

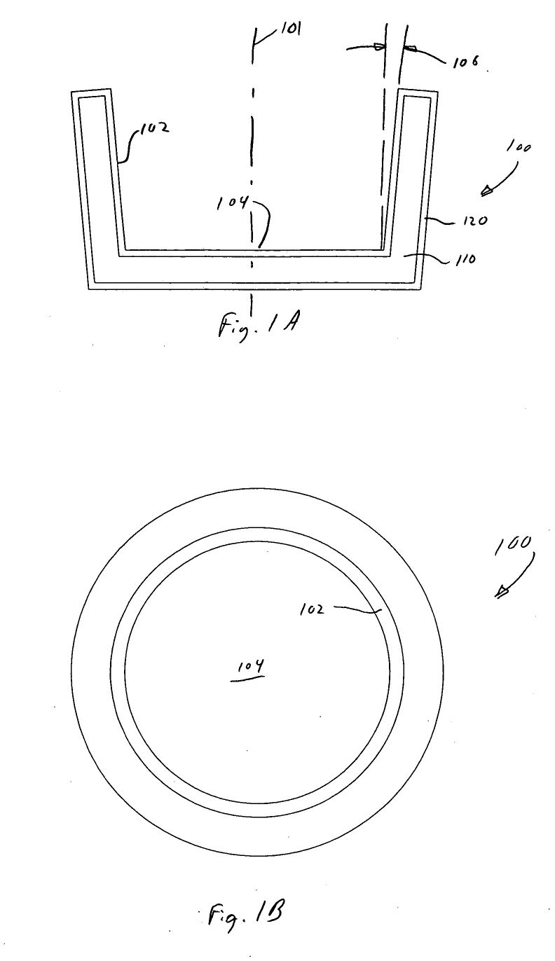

FIGS. 1A and 1B show a crucible 100, having a central axis 101, according to one embodiment of the invention. In one embodiment, the crucible 100 is used to fabricate an ingot of semiconductor material. In one embodiment, the crucible 100 is used to fabricate an ingot of silicon material. In one embodiment, the crucible 100 is used to fabricate an ingot of polycrystalline semiconductor material.

The crucible 100 includes a base container 110. The base container includes a bottom 104 and sides 102. As shown in FIG. 1A, in one embodiment, the sides 102 form a taper angle 106 in relation to a line perpendicular to the bottom 104. In one embodiment, the taper angle is between approximately 1 and 3 degrees. A substantially cylindrical crucible 100 is illustrated in FIG. 1, although the invention is not so limited. Other geometries include cubes, rectangles, hemispheres, etc.

In one embodiment, the base container 110 includes a silicon dioxide base container. Acceptable forms of silicon dioxide material include, but are not limited to, fused silica; slip cast quartz, other grades and processes of quartz, etc. In one embodiment, the base container 110 includes a carbon base container. Acceptable forms of carbon material include, but are not limited to, amorphous graphite, graphite with an oriented grain structure, etc. In one embodiment, graphite material includes purified graphite. In one embodiment, the central axis 101 of the crucible is oriented substantially perpendicular to an orientation of graphite grains. Although specific material examples such as silicon dioxide and carbon are discussed, the invention is not so limited. Other acceptable materials for the base container 110 are within the scope of embodiments of the invention.

Base containers formed from graphite as described above provide a number of advantages. One advantage includes a coefficient of thermal expansion that is lower that a coefficient of thermal expansion for silicon. Upon cooling, a silicon ingot will therefore shrink faster than the crucible it is contained within. This reduces or eliminates any outward forces that cause destructive fracture of other crucibles using other base container materials. Another advantage of base containers formed from graphite as described above includes utilizing anisotropic coefficients of thermal expansion in oriented grain graphite material. Orienting the central axis 101 to be substantially perpendicular to an orientation of graphite grains further enhances a desired coefficient of thermal expansion for the base container 110 to provide ease of removal of a cooled ingot, and reduces fracture of crucibles.

A coating layer 120 is further shown in FIG. 1A. In one embodiment, the coating layer 120 includes boron nitride (BN) material. In one embodiment the coating layer 120 includes silicon nitride (Si₃N₄) material. In one embodiment, the coating layer 120 includes a composite coating layer, having portions of two or more different materials. In one embodiment, a composite coating layer includes boron nitride (BN) material and silicon nitride (Si₃N₄) material. In one embodiment, the boron nitride material and the silicon nitride material are both of a high purity of approximately 99.999% pure. High purity reduces a possibility of unwanted contaminants to the ingot process.

Coating layers including boron nitride provide a number of advantages. One advantage includes release properties with respect to silicon ingots. Liquid silicon does not easily adhere to boron nitride material on the walls 102 and bottom 104 of the base container 110. Another advantage of embodiments with boron nitride in the coating layer is that if any impurities are introduced to the ingot, the potential impurity is compatible with integrated circuit chip processing. Although in some embodiments, a small amount of boron impurities are introduced into the ingot during formation, boron is typically an acceptable impurity in integrated circuit chip processing. In one embodiment, the presence of boron can be used in wafer design to reduce unwanted conduction.

FIG. 2 shows a crucible 200 according to one embodiment of the invention. The crucible 200 includes a base container 210. The base container includes a bottom 204 and sides 202. In one embodiment, the base container 210 includes a silicon dioxide base container. In one embodiment, the base container 210 includes a carbon base container. In one embodiment, the base container 210 includes graphite. In one embodiment, a central axis 201 of the crucible is oriented substantially perpendicular to an orientation of graphite grains. Although specific material examples such as silicon dioxide and carbon are discussed, the invention is not so limited. Other acceptable materials for the base container 210 are within the scope of embodiments of the invention.

A first coating layer 220 is shown forming an interface with the base container 210. A second coating layer 230 is shown forming an interface with the first coating layer 220. In one embodiment, the first coating layer 220 and the second coating layer 230 together form a composite coating layer. Although in FIG. 2, the composite coating layer configuration includes two continuous layers formed one over the other, alternative composite coating layers configurations, such as a matrix and dispersed phase composite for example, are also within the scope of the invention.

In one embodiment, the first coating layer 220 includes boron nitride. In one embodiment, the second coating layer 230 includes silicon nitride. In one embodiment, the first coating layer 220 includes silicon nitride and the second coating layer 230 includes boron nitride. An advantage of using boron nitride as the first coating layer 220 includes the property that boron impurity diffusion into a silicon melt is reduced by substantially covering the boron nitride first coating layer 220 with a second coating layer 230. An advantage of using silicon nitride as the second coating layer 230 includes the property that silicon nitride has a low reactivity with liquid silicon. Advantages of a composite coating layer including a boron nitride first coating layer 220 and a silicon nitride second layer 230 includes the ability to substantially prevent liquid silicon from contacting walls of the base container 210 while reducing an amount of impurities introduced into the liquid silicon. Another advantage of a composite coating layer including a boron nitride first coating layer 220 and a silicon nitride second layer 230 includes enhanced releaseability of a cooled silicon ingot from coated surfaces such as the walls 202 and bottom 204 of the crucible 200.

A silicon nitride coating, when used by itself has problems such as coating porosity that allows liquid silicon to penetrate the silicon nitride coating and come into contact with a base container material. As discussed above, this contact can lead to unacceptable impurities being introduced in to the liquid silicon. Further, silicon will cool into pores of a silicon nitride coating layer and cause a chemical/mechanical bond with surfaces of the silicon nitride coating if there are no additional driving forces to prevent flow into the pores. This can cause difficulty in removing the ingot from the crucible. An advantage of embodiments using boron nitride includes a surface energy force with respect to liquid silicon that keeps liquid silicon out of pores in a silicon nitride coating.

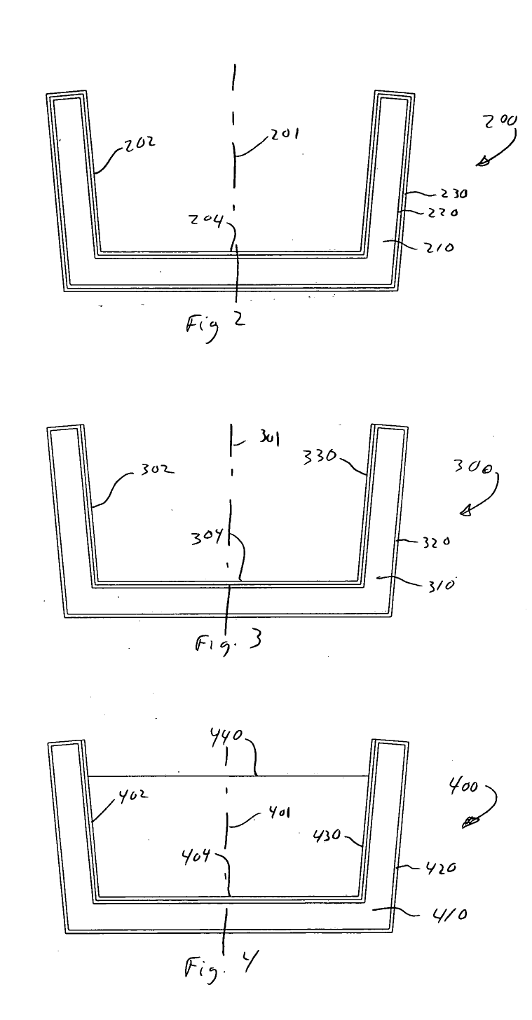

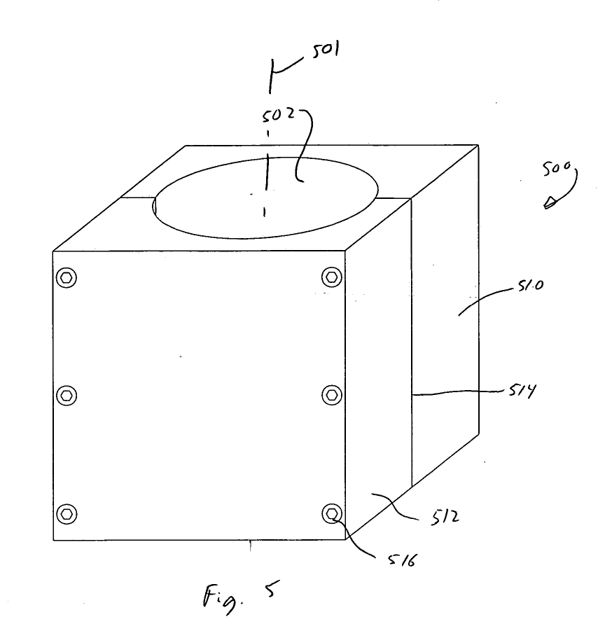

FIG. 3 shows a crucible 300 according to one embodiment of the invention. The crucible 300 includes a base container 310. The base container includes a bottom 304 and sides 302. In one embodiment, the base container 310 includes a silicon dioxide base container. In one embodiment, the base container 310 includes a carbon base container. In one embodiment, the base container 310 includes graphite. In one embodiment, a central axis 301 of the crucible is oriented substantially perpendicular to an orientation of graphite grains. Although specific material examples such as silicon dioxide and carbon are discussed, the invention is not so limited. Other acceptable materials for the base container 310 are within the scope of embodiments of the invention.

A first coating layer 320 is shown forming an interface with the base container 310. A second coating layer 330 is shown forming an interface with the first coating layer 320. In one embodiment, the first coating layer 320 and the second coating layer 330 together form a composite coating layer. In one embodiment, the first coating layer 320 includes boron nitride. In one embodiment, the second coating layer 330 includes silicon nitride.

In FIG. 3, the second coating layer 330 is shown only covering interior surfaces such as the walls 302 and bottom 304 of the crucible 300. In one embodiment, all surfaces of the base container 310 are covered by the first coating layer 320. One advantage of covering external surfaces of the base container 310 includes a suppression of contaminants, such as carbon from a graphite crucible for example, through the atmosphere into the liquid silicon. An advantage of covering only interior surfaces such as the walls 302 and bottom 304 of the crucible 300 with the second coating layer 330 includes cost savings. Only covering the interior surfaces of the crucible 300 with the second coating 330 is effectuve beacause only these surfaces experience direct contact with liquid silicon.

FIG. 4 shows a crucible 400 according to one embodiment of the invention. The crucible 400 includes a base container 410. The base container includes a bottom 404 and sides 402. In one embodiment, the base container 410 includes a silicon dioxide base container. In one embodiment, the base container 410 includes a carbon base container. In one embodiment, the base container 410 includes graphite. In one embodiment, a central axis 401 of the crucible is oriented substantially perpendicular to an orientation of graphite grains. An amount of liquid material 440 is illustrated in FIG. 4 filling a portion of the crucible 400. In one embodiment, the liquid material 440 includes liquid silicon. Other semiconductor materials are also within the scope of the invention. As noted above, the liquid material 440 is only in contact with interior surfaces such as the walls 402 and bottom 404 of the crucible 400.

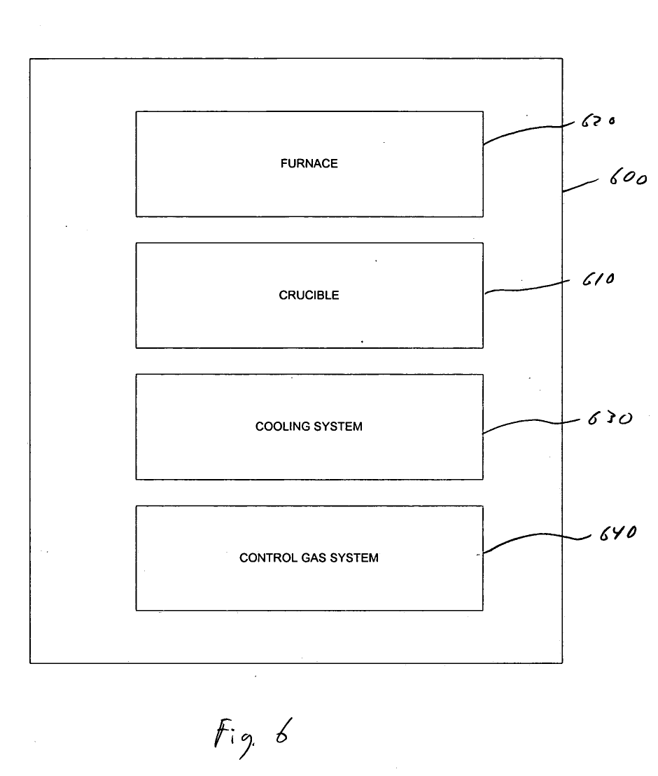

FIG. 5 shows a crucible 500 according to one embodiment of the invention. The crucible 500 includes a first base container portion 512 and a second base container portion 514. Although two base container portions are illustrated in FIG. 5, other numbers of base container portions are also within the scope of the invention. In one embodiment, the first base container portion 512 and the second base container portion 514 form a bottom (not shown) and sides 502. A number of fasteners 516 are shown in FIG. 5 to hold the first base container portion 512 and the second base container portion 514 together during melting. In one embodiment, the number of fasteners 516 are removable after cooling of the ingot to facilitate removal of the ingot from the crucible 500.

In one embodiment, the first base container portion 512 and the second base container portion 514 include a silicon dioxide material. In one embodiment, the first base container portion 512 and the second base container portion 514 include a carbon material. In one embodiment, the first base container portion 512 and the second base container portion 514 include graphite. In one embodiment, a central axis 501 of the crucible 500 is oriented substantially perpendicular to an orientation of graphite grains. Although specific material examples such as silicon dioxide and carbon are discussed, the invention is not so limited. Other acceptable materials for the first base container portion 512 and the second base container portion 514 are within the scope of embodiments of the invention. A substantially cylindrical ingot form is illustrated in FIG. 5, although the invention is not so limited. Other geometries include cubes, rectangles, hemispheres, etc.

In one embodiment, surfaces of the first base container portion 512 and the second base container portion 514 include a coating layer similar to embodiments discussed above. In one embodiment, all surfaces of the first base container portion 512 and the second base container portion 514 are coated with boron nitride. In one embodiment, at least the interior surfaces of the first base container portion 512 and the second base container portion 514 are coated with silicon nitride over boron nitride.

FIG. 6 shows an ingot system 600. In one embodiment, the ingot system is used to form silicon ingots. The ingot system 600 includes a crucible 610 as described in selected embodiments above. The ingot system 600 includes a furnace 620 that is adapted to heat the crucible 610 along with its contents such as silicon, to form a silicon ingot.

In one embodiment, the ingot system 600 includes a cooling system 630. In one embodiment, the cooling system is used to control a preferred direction of cooling in the crucible 610. In one embodiment, heat is conducted from a bottom of the crucible preferentially, in contrast to cooling the crucible 610 from all sides at the same time. Cooling preferentially, such as cooling from a bottom of the crucible, forms an anisotropic grain structure in the ingot. Preferential orientation of grains in an ingot such as a silicon ingot leads to desirable properties such as preferential electrical conduction, preferential diffusion characteristics, etc.

In one embodiment, the ingot system 600 includes a control gas system 640. In one embodiment, the control gas system provides a desired gas atmosphere that surrounds the crucible and the liquid material during the melt. In one embodiment, the control gas includes nitrogen. An advantage of including nitrogen is that the presence of an amount of nitrogen suppresses chemical reactions that drive a dissociation of nitrogen containing compounds. For example, nitrides such as boron nitride and silicon nitride tend to not dissociate into boron and nitrogen or silicon and nitrogen if a certain amount of nitrogen is present in the control gas. Reducing these reactions in turn produces fewer undesirable impurities that can contaminate the liquid being melted. In one embodiment, the control gas further includes an amount of inert gas such as argon. In one embodiment, the control gas includes between 5 and 10 percent nitrogen with the remaining gas being argon.

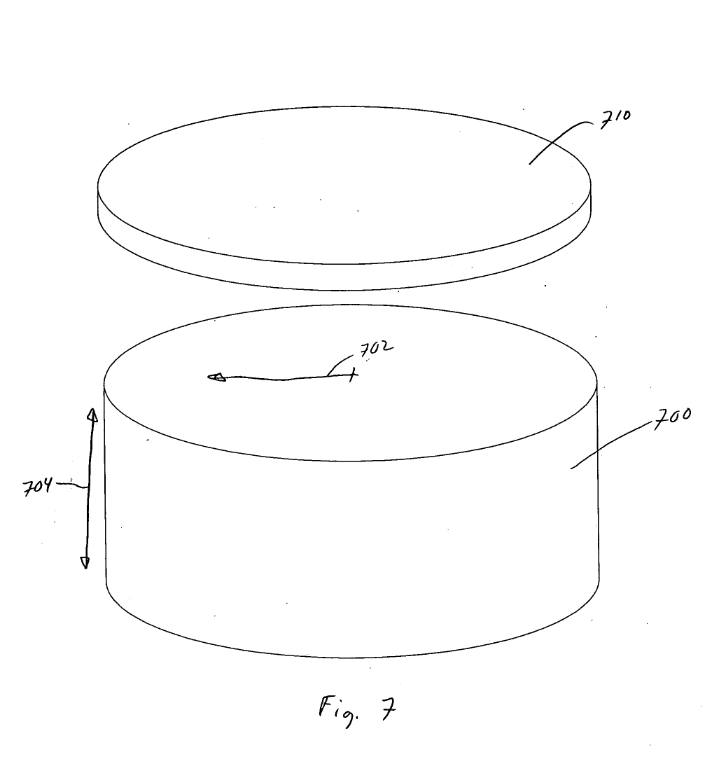

FIG. 7 shows an ingot 700 formed using methods, crucibles, and systems as described above. In contrast to common semiconductor wafers, the ingot 700 is a multicrystalline ingot. As discussed above, single crystal wafers are typically used to fabricate devices such as transistors. A radial direction of the ingot 700 is indicated by arrow 702. Likewise, a longitudinal direction of the ingot 700 is indicated by arrow 704. In one embodiment, as described above, a grain structure of the ingot 700 is preferential with respect to these ingot coordinate directions. Further shown in FIG. 7 is a multicrystalline wafer 710 that has been cut from the ingot 700.

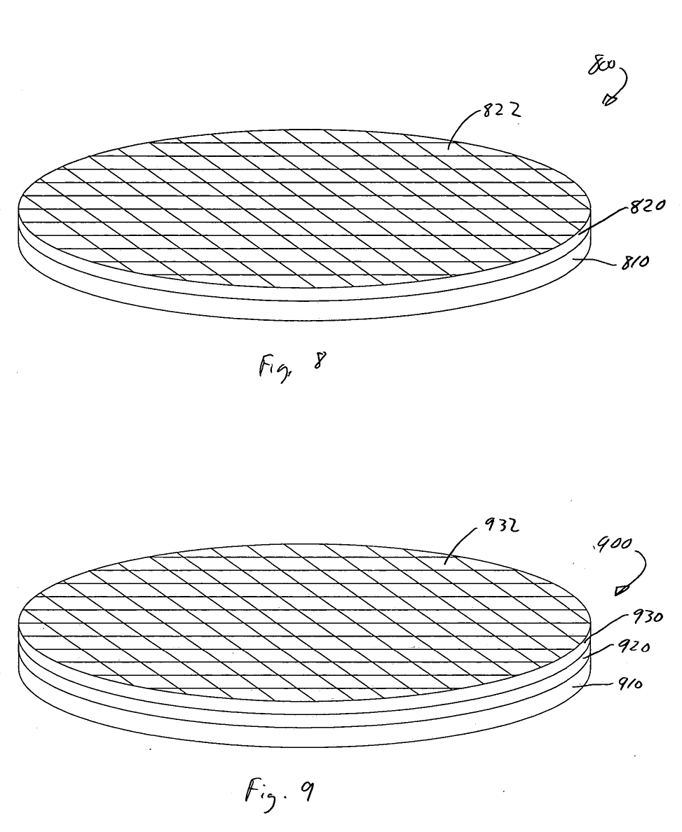

FIG. 8 shows a composite wafer 800 according to one embodiment of the invention. The composite wafer 800 includes a handling wafer portion 810 and a device portion 820. In one embodiment, the device portion 820 includes single crystal silicon. In one embodiment, the handling wafer portion 810 includes a multicrystalline wafer formed by methods described above. Also shown in FIG. 8 are a number of individual chips 822 outlined on the device portion 820 of the composite wafer 800.

Advantages of the composite wafer 800 include a lower cost material in the handling wafer portion 810 while maintaining a device portion 820 for formation of chips 822 with integrated circuits. Using devices and methods described above, one advantage includes a reduction in manufacturing cost of the handling wafer portion 810 due to a reusable crucible. Another advantage of devices and methods described above includes an ability to form a handling wafer portion 810 with a low impurity concentration that is acceptable to the integrated circuit chip industry. While the handling wafer portion 810 as shown in FIG. 8 is physically separate from the device portion 820, during semiconductor processing techniques, a contaminated handling wafer portion 810 could introduce unwanted impurities to the device portion 820 through mechanisms such as diffusion. Another advantage of devices and methods described above includes an increased mechanical integrity of the composite wafer 800 at a low cost due to a larger thickness of the composite wafer 800 without the high cost of a completely single crystal wafer.

FIG. 9 shows a composite wafer 900 according to one embodiment of the invention. The composite wafer 900 includes a handling wafer portion 910 and a device portion 930. The composite wafer 900 further includes an isolation layer 920 separating the handling wafer portion 910 from the device portion 930. In one embodiment, the device portion 930 includes single crystal silicon. In one embodiment, the handling wafer portion 910 includes a multicrystalline wafer formed by methods described above. Also shown in FIG. 9 are a number of individual chips 932 outlined on the device portion 930 of the composite wafer 900. In one embodiment, the composite wafer 900 operates as a silicon-on-insulator (SOI) wafer. One of ordinary skill in the art, having the benefit of the present disclosure will recognize that SOI wafers possess certain electrical advantages for the design of integrated circuit chips. Similar to embodiments described above and shown in FIG. 8, the composite wafer 900 includes a number of advantages such as low cost, increased mechanical integrity, and low impurity concentrations.

While a number of advantages of embodiments of the invention are described, the above lists are not intended to be exhaustive. Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of embodiments described above. It is to be understood that the above description is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

What is claimed is:

1. A crucible comprising:
a base container to contain liquid silicon material;
a coating layer covering at least a portion of the base container, wherein the coating layer includes boron nitride.

2. The crucible of claim 1, wherein the base container includes a material having a coefficient of thermal expansion less than silicon.

3. The crucible of claim 1, wherein the base container includes graphite.

4. The crucible of claim 1, wherein the base container is integrally formed.

5. The crucible of claim 1, wherein the base container includes multiple components.

6. The crucible of claim 1, wherein the coating layer further includes silicon nitride.

7. The crucible of claim 6, wherein the coating layer includes a first layer of boron nitride adjacent to the base container and a second layer of silicon nitride over the layer of boron nitride.

8. An ingot system, comprising:
a furnace;
a crucible, including:
a base container to contain liquid silicon material;
a coating layer covering at least a portion of the base container, wherein the coating layer includes boron nitride; and
a cooling system to extract heat from the crucible.

9. The ingot system of claim 8, wherein the cooling system includes a directional solidification cooling system.

10. The ingot system of claim 8, further including a control gas system.

11. The ingot system of claim 8, wherein the base container includes graphite.

12. The ingot system of claim 8, wherein the base container includes silicon dioxide.

13. The ingot system of claim 8, wherein the coating layer includes a first layer of boron nitride adjacent to the base container and a second layer of silicon nitride over the layer of boron nitride.

14. A method of forming a silicon ingot, comprising:
coating a base container with a layer including boron nitride;
melting silicon material in the base container wherein the layer provides an interface between the base container and the silicon material;
cooling the molten silicon material; and
removing the cooled silicon material from the base container.

15. The method of claim 14, wherein coating the base container includes coating a graphite base container.

16. The method of claim 14, wherein coating the base container includes coating a base container with a coating that includes boron nitride and silicon nitride.

17. The method of claim 14, wherein cooling molten silicon includes directional solidification of silicon.

18. The method of claim 14, wherein removing the cooled silicon material from the base container includes non-destructive removal of the cooled silicon material from the base container.

19. The method of claim 14, wherein melting silicon material in the base container includes melting in an atmosphere that includes nitrogen.

20. The method of claim 14, wherein melting silicon material in the base container includes melting in an argon and nitrogen atmosphere.

21. A method of forming a silicon wafer comprising:
coating a base container with a layer including boron nitride;
melting silicon material in the base container wherein the layer provides an interface between the base container and the silicon material;
solidifying the molten silicon material;
removing the solidified silicon material from the base container;
attaching a semiconductor wafer to at least a portion of the solidified silicon material to form a composite wafer.

22. The method of claim 21, wherein the semiconductor wafer includes single crystal silicon.

23. The method of claim 21, further including coupling an insulator layer between the semiconductor wafer and the portion of the solidified silicon material.

24. The method of claim 21, further including forming a number of electronic devices on the semiconductor wafer.

25. The method of claim 24, wherein forming a number of electronic devices includes forming a number of transistors.

26. The method of claim 21, wherein coating the base container includes coating a graphite base container.

27. The method of claim 21, wherein coating the base container includes coating a base container with a coating that includes boron nitride and silicon nitride.
